(19) United States
(12) Patent Application Publication
(10) Pub. No.: US 2021/0111222 A1
(43) Pub. Date: Apr. 15, 2021

(54) PROCESS TO IMPROVE INTERFACE STATE DENSITY Dit ON DEEP TRENCH ISOLATION (DTI) FOR CMOS IMAGE SENSOR

(71) Applicant: Applied Materials, Inc., Santa Clara, CA (US)

(72) Inventors: Philip Hsin-hua Li, San Jose, CA (US); Toshihiko Miyashita, San Jose, CA (US); Ellie Yieh, San Jose, CA (US); Srinivas D. Nemani, Saratoga, CA (US); Seshadri Ramaswami, Saratoga, CA (US); Nikolaos Bekiaris, Campbell, CA (US)

(21) Appl. No.: 16/653,762

(22) Filed: Oct. 15, 2019

(51) Int. Cl. H01L 27/146

(52) U.S. Cl. CPC H01L 27/14698; H01L 27/14645; H01L 27/1462; H01L 27/1464; H01L 27/14627; H01L 27/1463; H01L 27/14621

(57) ABSTRACT

Embodiments disclosed herein include CMOS image sensors and methods of forming such devices. In an embodiment, a method of forming a CMOS image sensor comprises pressurizing a chamber with a gas comprising hydrogen, and annealing a substrate in the pressurized chamber. In an embodiment the substrate comprises the CMOS image sensor. In an embodiment, the CMOS image sensor comprises a semiconductor body and a trench around a perimeter the semiconductor body, wherein the trench is filled with a high-k oxide that directly contacts the semiconductor body. In an embodiment, the method further comprises, depressurizing the chamber.

### BACKGROUND

### 1) Field

Embodiments relate to the field of semiconductor manufacturing and, in particular, to systems and methods for reducing interface state density (Dᵢₜ) on deep trench isolation (DTI) for CMOS image sensors.

### 2) Description of Related Art

Complementary metal-oxide-semiconductor (CMOS) image sensors convert electromagnetic radiation into an electrical signal. As shown in FIG. 1A, a CMOS image sensor 100 may comprise a plurality of cells. Each cell may comprise a semiconductor body 110 that is defined by a trench 115. The trench 115 is typically filled with a high-k dielectric 120. The semiconductor body 110 is a photodiode that converts incoming electromagnetic radiation into the electrical signal. The trenches 115 isolate each semiconductor body 110 and limit the cross-talk between cells.

For example, FIG. 1B provides a cross-sectional illustration that depicts incoming electromagnetic radiation 145 that enters the semiconductor body 110 at a non-orthogonal angle to the surface. As such, the electromagnetic radiation will ultimately intersect the high-k dielectric 120 of the trench 115. If the trench 115 were not present, the electromagnetic radiation 145 would continue to pass into the neighboring semiconductor body 110 (as indicated by dashed line 145′).

However, the presence of the high-k dielectric 120 in the trench 115 is not without issue. Particularly, the interface between the high-k dielectric 120 and the semiconductor body has been shown to be a significant source of interface traps. That is, the interface state density (Dᵢₜ) is relatively high (e.g., 2.0e11/cm² eV or higher). A high Dᵢₜ along the trench 115 provides many sites for electron-hole recombination, and results in a high leakage current (sometimes referred to as dark current). This leakage current significantly reduces the signal-to-noise ratio of the CMOS image sensor and results in a decrease in the image quality.

### SUMMARY

Embodiments disclosed herein include CMOS image sensors and methods of forming such devices. In an embodiment, a method of forming a CMOS image sensor comprises pressurizing a chamber with a gas comprising hydrogen, and annealing a substrate in the pressurized chamber. In an embodiment the substrate comprises the CMOS image sensor. In an embodiment, the CMOS image sensor comprises a semiconductor body and a trench around a perimeter the semiconductor body, wherein the trench is filled with a high-k oxide that directly contacts the semiconductor body. In an embodiment, the method further comprises, depressurizing the chamber.

Embodiments disclosed herein may further comprise a CMOS image sensor. In an embodiment, the CMOS image sensor comprises a semiconductor substrate with a first surface and a second surface opposite from the first surface, and a trench into the first surface of the semiconductor substrate, wherein the trench defines a semiconductor body in the semiconductor substrate. In an embodiment, the CMOS image sensor further comprises a high-k oxide filling the trench, wherein an interface state density (Dᵢₜ) at an interface between the high-k oxide and the semiconductor body is less than 2.0e11/cm² eV. In an embodiment, the CMOS image sensor further comprises an interconnect.

In an embodiment, a method of forming a CMOS image sensor may also comprise placing a substrate comprising a CMOS image sensor into a chamber, wherein the CMOS image sensor comprises a semiconductor substrate with a first surface and a second surface opposite from the first surface, a trench into the first surface of the semiconductor substrate, wherein the trench defines a semiconductor body in the semiconductor substrate, a high-k oxide filling the trench, and an interconnect stack over the second surface of the semiconductor substrate. In an embodiment, the method may further comprise pressurizing the chamber with a gas comprising H₂ and/or deuterium, annealing the substrate in the pressurized chamber, and depressurizing the chamber.

### BRIEF DESCRIPTION OF THE DRAWINGS

FIG. 1A is a plan view illustration of a plurality of cells in a CMOS image sensor.

FIG. 1B is a cross-sectional illustration of cells in a CMOS image sensor and a light that enters a cell at a non-orthogonal angle.

FIG. 2A is an energy level diagram of an interface between a high-k dielectric trench and a semiconductor body of a CMOS image sensor that illustrates the presence of interface traps and border traps that result in leakage current during operation of the CMOS image sensor, in accordance with an embodiment.

FIG. 2B is an energy level diagram of the interface after a pressurized annealing treatment that illustrates the filling of the interface traps and the border traps, in accordance with an embodiment.

FIG. 3A is a cross-sectional illustration of a cell of a CMOS image sensor, in accordance with an embodiment.

FIG. 3B is a zoomed in cross-section of the interface between a high-k dielectric trench and a semiconductor body of the cell in FIG. 3A, in accordance with an embodiment.

FIG. 4A is a process flow diagram of a process for decreasing the interface state density of the interface between a high-k dielectric trench and a semiconductor body in a CMOS image sensor, in accordance with an embodiment.

FIG. 4B is a graph of pressure and time during the process described in FIG. 4A, in accordance with an embodiment.

FIG. 5 is a cross-sectional illustration of a processing chamber for implementing a pressurized anneal for decreasing the interface state density in CMOS image sensors, in accordance with an embodiment.

FIG. 6 illustrates a block diagram of an exemplary computer system that may be used in conjunction with processes for reducing the Dᵢₜ in a CMOS image sensor, in accordance with an embodiment.

### DETAILED DESCRIPTION

Systems and methods described herein include processes for decreasing the interface state density (Dᵢₜ) in deep trench isolation (DTI) structures for CMOS image sensors. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, in a CMOS image sensor, the interface between a high-k dielectric and the semiconductor body results in a high concentration of interface traps. These interface traps lead to high leakage currents (i.e., dark currents) and decreases the image quality of the CMOS image sensor. Accordingly, embodiments disclosed herein include methods for treating CMOS image sensors in order to decrease the interface state density (Dᵢₜ). As such, there are fewer sites (e.g., interface trap sites) where undesirable recombination occurs and the leakage current is reduced.

Particularly, embodiments disclosed herein include backside illuminated CMOS image sensors that are treated with a high pressure anneal. The backside illumination increases the amount of electromagnetic radiation that reaches the photodiode. This is because the interconnect stack is moved to the backside of the semiconductor body, and the electromagnetic radiation no longer needs to pass through the interconnect stack. Furthermore, the high pressure anneal fills a significant amount of the interface trap sites and border trap sites. For example, a high pressure anneal (e.g., 5 bar or higher) using a gas comprising hydrogen (e.g., H₂ and/or deuterium D₂) is used to fill the trap sites. It has been shown that such high pressure anneals can reduce the Dᵢₜ by at least an order of magnitude. For example, treatments in accordance with embodiments disclosed herein have shown a reduction a Dᵢₜ from approximately 2.0e11/cm² eV to approximately 1.5e10/cm² eV.

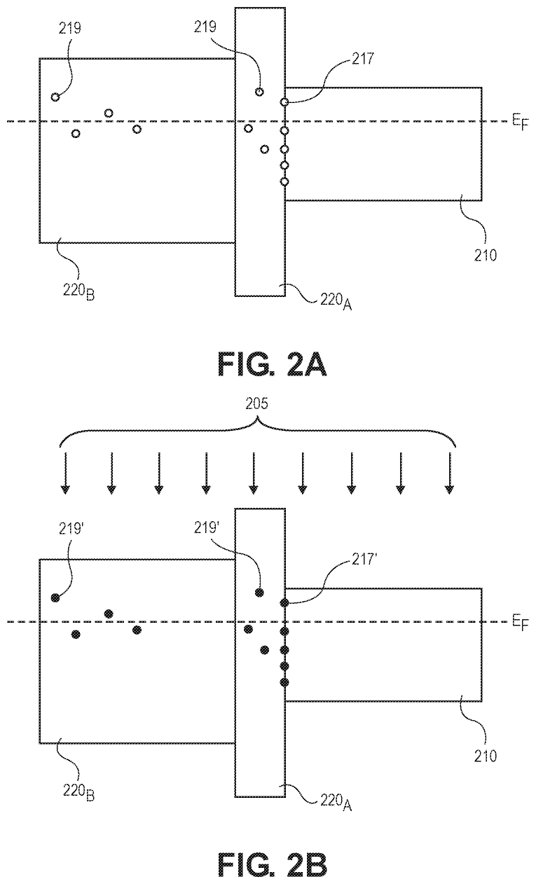

Referring now to FIG. 2A, an energy level diagram of the interface between a semiconductor body 210 and a high-k dielectric 220 in a CMOS image sensor is shown, in accordance with an embodiment. In the illustrated embodiment, the high-k dielectric 220 is illustrated as having a first high-k material 220A and a second high-k material 220B. However, it is to be appreciated that similar diagrams may be provided for interfaces where there is a single high-k material 220 or more than two high-k materials 220. The interface between the semiconductor body 210 and the first high-k dielectric 220 may be populated by interface traps 217. Additional defects 219 may be formed throughout the body of the first high-k dielectric 220A and the second high-k dielectric 220B. Such defects may be referred to as border traps 219.

Referring now to FIG. 2B, an energy level diagram of the interface after a treatment 205 is shown, in accordance with an embodiment. The treatment 205 may comprise a pressurized anneal. The pressure may be supplied by a gas comprising hydrogen. For example, the gas may comprise hydrogen gas H₂ and/or deuterium D₂. The pressure drives the hydrogen species to the interfaces, where they are captured by the interface traps 217 to form neutralized interface traps 217′. Similarly, the border traps 219 may capture hydrogen to form neutralized border traps 219′.

It is to be appreciated that the interface traps 217 and the border traps 219 are illustrated schematically in FIGS. 2A and 2B and are not representative of the actual size and number of such traps. However, while it may be difficult to provide imaging that depicts the different traps, the interface state density (Dᵢₜ) can be calculated using various methods well known to those skilled in the art. For example, differential capacitance versus gate bias (C-V) measurements may be used to determine the Dᵢₜ before and after the pressurized annealing treatment. In some embodiments, the pressurized annealing treatment may reduce the Dᵢₜ to less than 2.0e11/cm⁻²·eV. In some embodiments, the pressurized annealing treatment may reduce the Dᵢₜ by an order of magnitude or more. For example, the Dᵢₜ may be reduced from approximately 2.0e11/cm² eV to approximately 1.5e10/cm² eV.

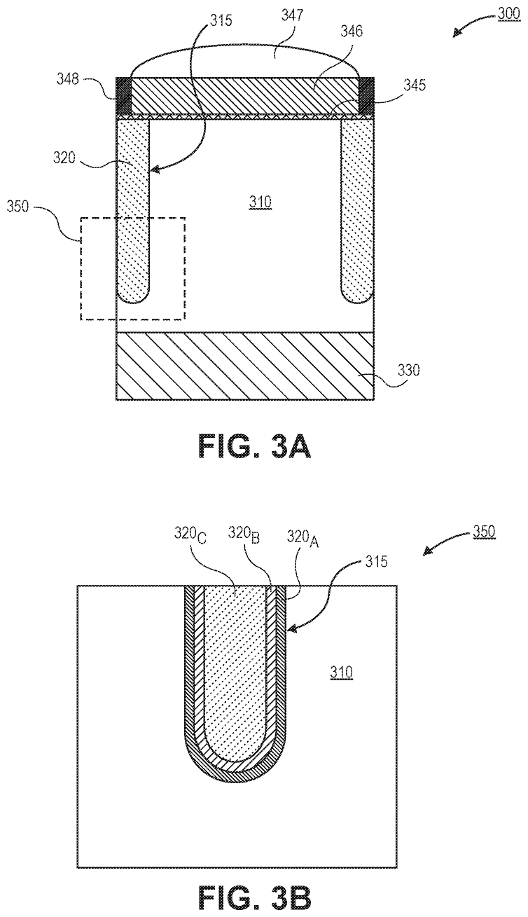

Referring now to FIG. 3A, a cross-sectional illustration of a cell of a CMOS image sensor 300 is shown, in accordance with an embodiment. In an embodiment, the cell may comprise a semiconductor body 310 that is disposed over an interconnect stack 330. The semiconductor body 310 may be any suitable semiconductor material for forming a photodiode. For example, the semiconductor body 310 may comprise silicon. The semiconductor body 310 may also include dopants and the like.

In an embodiment, the interconnect stack 330 comprises conductive features (e.g., traces, vias, pads, etc.) that are surrounded by an insulating material. The conductive features are omitted in FIG. 3A for simplicity. However, it is to be appreciated that the conductive features and the insulating material of the interconnect stack 330 are provided on a bottom surface of the semiconductor body 310. Accordingly, light does not need to pass through the interconnect stack 330 in order to reach the semiconductor body 310. That is, the CMOS image sensor 300 may be referred to as a backside illuminated CMOS image sensor since the surface that the interconnect stack 330 is located over is typically referred to as the front side of the CMOS image sensor 300.

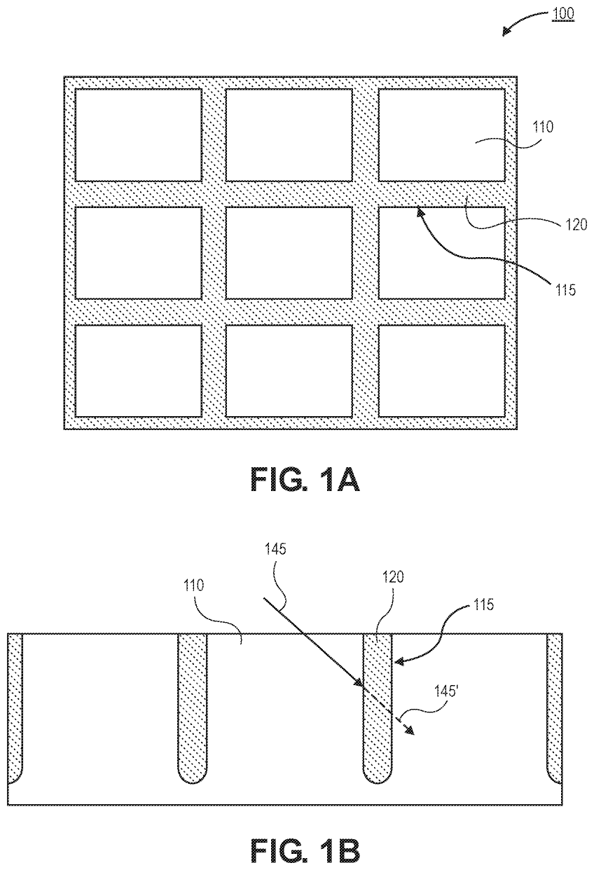

In an embodiment, the cell of the CMOS image sensor 300 may be defined by a trench 315 that extends into the semiconductor material. In the illustrated embodiment, the trench 315 does not extend entirely through the semiconductor material. However, in other embodiments, the trench 315 may pass entirely through the semiconductor material and contact the interconnect stack 330. The trench 315 may substantially surround the semiconductor body 310. For example, the trench 315 is shown on the left side and the right side of the semiconductor body 310 in FIG. 3A. However, it is to be appreciated that the trench 315 may wrap around the semiconductor body 310 out of the plane of FIG. 3A (e.g., similar to the trench 115 shown in the plan view of the CMOS image sensor 100 in FIG. 1A). In an embodiment, the trench 315 is typically a high aspect ratio trench in order to minimize the surface area of the trench and allow more room for semiconductor materials. In some embodiments, the trench 315 may be referred to as a deep trench isolation (DTI).

In an embodiment, the trench 315 is filled with a high-k dielectric 320. As used herein, a high-k dielectric may refer to a material with a dielectric constant that is substantially equal to that of silicon dioxide or greater. For example, a high-k dielectric material may refer to a dielectric material with a dielectric constant that is approximately 3.9 or higher. In FIG. 3A the high-k dielectric 320 is shown as a monolithic material. However, in some embodiments, the high-k dielectric 320 may comprise a plurality of different layers.

For example, FIG. 3B illustrates a zoomed in portion 350 of FIG. 3A in order to illustrate an additional embodiment where a plurality of different layers are used to fill the trench 315. As shown, a first liner 320A lines the trench 315, a second liner 320B is over the first liner 320A, and a fill layer 320c fills a remaining portion of the trench 315. In an embodiment, the different portions 320A, 320B, and 320c may include any high-k dielectric materials. For example, the first liner 320A may comprise Al₂O₃, the second liner 320B may comprise Ta₂O₅, and the fill layer 320c may comprise SiO₂. In other embodiments, the second liner 320B may be omitted, leaving only a first liner 320A and a fill layer 320c. In other embodiments, additional high-k layers may also be added between the second liner 320B and the fill layer 320c. In FIGS. 3A and 3B, the trench 315 is completely filled. However, in some embodiments, the high aspect ratio of the trench 315 may result in the formation of a void. That is, the trench 315 may not be entirely filled with a high-k dielectric in some embodiments.

Referring back to FIG. 3A, the cell may further comprise an optics stack over the top surface semiconductor body 310 and the high-k dielectric 320. The optics stack over the top surface (i.e., the backside surface) may include an anti-reflective coating (ARC) 345. In an embodiment, the optics stack may further comprise a filter 346 that is disposed over the ARC 345. The filter 346 may be a color filter or the like, typical of CMOS image sensors 300. In an embodiment, the filter 346 may be separated from neighboring cells by a grid that is opaque to a desired wavelength of electromagnetic radiation in order to define the boundary between cells. For example, the grid 348 may comprise tungsten. In an embodiment, the optics stack may further comprise a lens 347. The lens 347 may aid in focusing light into the semiconductor body 310.

In FIGS. 3A and 3B, an exemplary CMOS image sensor 300 is shown. However, it is to be appreciated that treatment methods in accordance with embodiments disclosed herein may be applicable to many different CMOS image sensor configurations. Particularly, the treatment methods disclosed herein are suitable for any CMOS image sensor that comprises an interface between a semiconductor material and a high-k dielectric. Such interfaces typically result in high interface state densities, which can be significantly lowered (e.g., by an order of magnitude or more) by pressurized annealing treatments in accordance with embodiments disclosed herein.

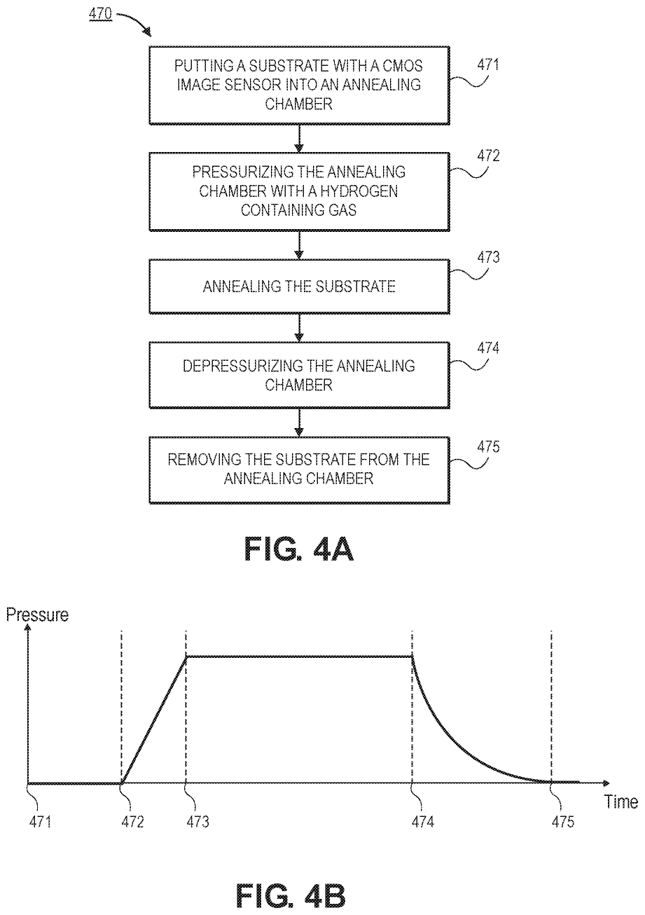

Referring now to FIGS. 4A and 4B, a process flow diagram of a process 470 for treating a CMOS image sensor to reduce the Dᵢₜ and a corresponding graph of time versus pressure within an annealing chamber are shown, respectively, in accordance with an embodiment. In an embodiment, process 470 begins with operation 471 which comprises putting a substrate with a CMOS image sensor into an annealing chamber. In an embodiment, the CMOS image sensor may be similar to the CMOS image sensor 300 described above with respect to FIGS. 3A and 3B. However, it is to be appreciated that any CMOS image sensor with an interface between a high-k dielectric and a semiconductor body may be treated with process 470. In a particular embodiment, the CMOS image sensor comprises a semiconductor body that is surrounded by a trench. In an embodiment, the trench is filled with a high-k dielectric material. The high-k dielectric material interfaces with the semiconductor body. As such, the interface between the two materials may be susceptible to a high interface state density (Dᵢₜ). For example, the interface state density Dᵢₜ of the CMOS image sensor may be approximately 2.0e11/cm² eV or greater. Accordingly, the CMOS image sensor may have a high leakage current. As shown in FIG. 4B, operation 471 is implemented at a time when the pressure is at a baseline level. For example, the baseline pressure may be atmospheric pressure.

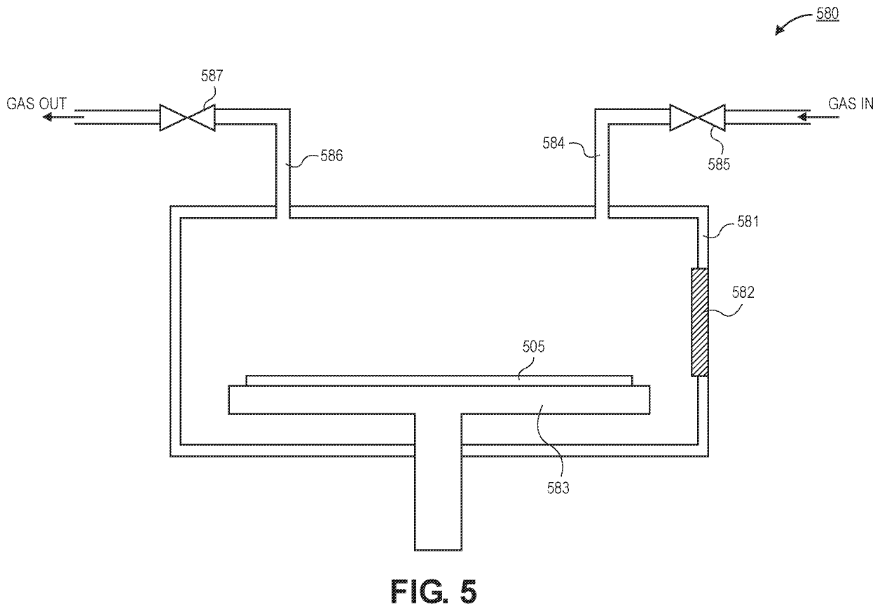

In an embodiment, the annealing chamber is a processing tool that is capable of heating the substrate at an elevated pressure. An example of such a processing tool is shown in the cross-sectional illustration in FIG. 5. As shown, the processing tool 580 includes a chamber 581. The chamber 581 may be a pressure vessel. That is, the chamber 581 is suitable for maintaining an elevated pressure. For example, the chamber 581 may be suitable for maintaining pressures up to approximately 75 bar or greater. In an embodiment, gas may be flown into the chamber 581 through a gas inlet 584. The gas inlet 584 may be fed with gas that passes through an inlet valve 585. In an embodiment, gas may be removed from the chamber 581 through a gas outlet 586. An outlet valve 587 controls the flow of gas out of the chamber 581. In an embodiment, the chamber 581 may include a door 582 through which a substrate 505 may pass to enter or exit the chamber 581.

In an embodiment, a support surface 583 for supporting a substrate 505 is provided in the chamber body 581. The support surface 583 may be a pedestal or the like. In some embodiments, the support surface 583 includes a chucking mechanism (e.g., a vacuum chuck or an electrostatic chuck) for securing the substrate 505 to the support surface 583.

In an embodiment, the support surface 583 further comprises a temperature control system in order to control the temperature of the substrate 505. For example, the temperature control system may be a resistive heater embedded in the support surface 583, or the like. In other embodiments, the temperature control system may be external to the support surface 583. For example, the temperature control system may be a heating lamp positioned above the support surface 583. In an embodiment, the temperature control system may be suitable for heating the substrate 505 to temperatures up to approximately 500° C.

In the illustrated embodiment, the processing tool 580 is shown as a discrete processing tool. That is, the processing tool 580 is shown as being a standalone tool that is not integrated with other processing chambers. However, in other embodiments, the processing tool 580 may be integrated with other processing chambers. For example, the processing tool 580 may be integrated into a cluster tool that includes other chambers (e.g., for implementing processes such as etching, material deposition, etc.).

Referring back to FIG. 4A, process 470 may continue with processing operation 472 which comprises, pressurizing the chamber with a hydrogen containing gas. In an embodiment, the hydrogen containing gas is flown into the chamber 581 through the gas inlet 584. In an embodiment, the hydrogen containing gas may comprise hydrogen (H₂) and/or deuterium (D₂). For example, the hydrogen containing gas may include 100% H₂, 100% D₂, or a combination of H₂ and D₂. In some embodiments, the hydrogen containing gas may also comprise inert gasses, such as argon (Ar) or the like. Embodiments may also comprise a hydrogen containing gas that includes nitrogen (N₂).

In an embodiment, the chamber may be pressurized to a pressure of approximately 5 bar or more. In a particular embodiment, the pressure within the chamber may be set up to approximately 75 bar. As shown in FIG. 4B, at operation 473 the pressure begins to increase until it reaches a desired pressure.

In an embodiment, process 470 may continue with operation 473, which includes annealing the substrate. In an embodiment, the annealing may be implemented at a temperature set point of approximately 25° C. or more. In some embodiments, the annealing may have a temperature set point between approximately 25° C. and 500° C. The annealing process may include a single temperature set point throughout the duration of the anneal, or the temperature set point may be modulated during the annealing process.

As shown in FIG. 4B, the annealing process begins at point 473 and continues for a desired period of time. In an embodiment, the annealing process may have a duration of approximately 10 minutes or more. In some embodiments, the annealing process may have a duration between approximately 10 minutes and approximately 60 minutes. In other embodiments, the annealing process may be longer than approximately 60 minutes. Some embodiments may include a substantially uniform pressure during the annealing process. However, it is to be appreciated that the pressure within the chamber may be non-uniform throughout the annealing process. For example, the pressure may increase or decrease during the annealing process.

In an embodiment, the pressurized annealing process provides a significant decrease in the interface state density Dᵢₜ. Due to the elevated pressure, the hydrogen is more easily able to access the interface between the high-k dielectric and the semiconductor body. Accordingly, the interface trap sites and the border trap sites are occupied by hydrogen. Since the trap sites are now occupied, they are no longer sources of leakage current, and the signal to noise ratio of the CMOS image sensor is improved.

In an embodiment, process 470 may continue with operation 474, which includes depressurizing the chamber 474. As shown in FIG. 4B, at point 474 the pressure is reduced back to the baseline pressure. For example, the pressure may be reduced back to approximately atmospheric pressure. In an embodiment, the pressure may be released by flowing gas out the gas outlet 586 by opening the outlet valve 587.

In an embodiment, process 470 may continue with operation 475, which includes removing the substrate 505 from the annealing chamber. For example, the substrate 505 may be removed from the support surface 583 with a wafer handling robot and exit the chamber 582 through the door 582.

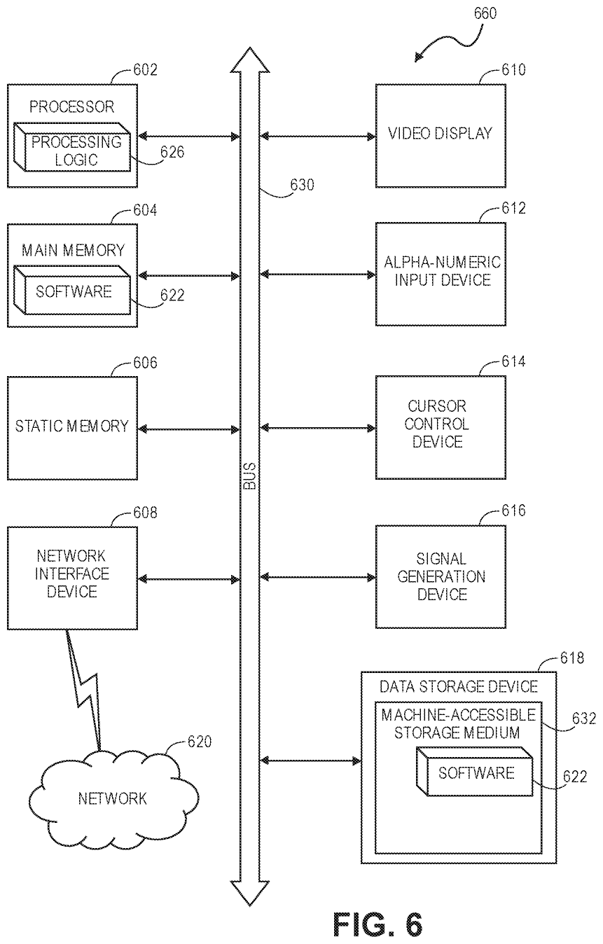

Referring now to FIG. 6, a block diagram of an exemplary computer system 660 of a processing tool is illustrated in accordance with an embodiment. In an embodiment, computer system 660 is coupled to and controls processing in the processing tool. Computer system 660 may be connected (e.g., networked) to other machines in a Local Area Network (LAN), an intranet, an extranet, or the Internet. Computer system 660 may operate in the capacity of a server or a client machine in a client-server network environment, or as a peer machine in a peer-to-peer (or distributed) network environment. Computer system 660 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 660, the term “machine” shall also be taken to include any collection of machines (e.g., computers) that individually or jointly execute a set (or multiple sets) of instructions to perform any one or more of the methodologies described herein.

Computer system 660 may include a computer program product, or software 622, having a non-transitory machine-readable medium having stored thereon instructions, which may be used to program computer system 660 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 660 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 660 may further include a system network interface device 608 for communicating with other devices or machines. The computer system 660 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 660, the main memory 604 and the system processor 602 also constituting machine-readable storage media. The software 622 may further be transmitted or received over a network 620 via the system network interface device 608. In an embodiment, the network interface device 608 may operate using RF coupling, optical coupling, acoustic coupling, or inductive coupling.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

1. A method of forming a CMOS image sensor, comprising:
pressurizing a chamber with a gas comprising hydrogen;
annealing a substrate positioned in the pressurized chamber, wherein a pressure of the pressurized chamber is non-uniform during the annealing, and wherein the substrate comprises the CMOS image sensor, and wherein the CMOS image sensor comprises:
a semiconductor body; and
a trench around a perimeter the semiconductor body, wherein the trench is filled with a high-k oxide that directly contacts the semiconductor body; and
depressurizing the chamber.

2. The method of claim 1, wherein the gas comprises H₂.

3. The method of claim 1, wherein the gas comprises deuterium.

4. The method of claim 1, wherein the gas further comprises an inert gas.

5. The method of claim 1, wherein a first interface state density (Dᵢₜ) of the CMOS image sensor before annealing is at least an order of magnitude higher than a second Dᵢₜ of the CMOS after annealing.

6. The method of claim 1, wherein the chamber is pressurized to at least 5 bar.

7. The method of claim 6, wherein the chamber is pressurized to between 10 bar and 75 bar.

8. The method of claim 1, wherein annealing the substrate comprises setting a pedestal on which the substrate is supported to a temperature of at least 25° C.

9. The method of claim 8, wherein the temperature is between 100° C. and 500° C.

10. The method of claim 1, wherein an annealing duration is between 10 minutes and 60 minutes.

11. The method of claim 1, wherein the semiconductor body comprises silicon (Si), and wherein the high-k oxide comprises aluminum oxide (Al₂O₃).

12. A CMOS image sensor, comprising:
a semiconductor substrate with a first surface and a second surface opposite from the first surface;
a trench entirely through the semiconductor substrate, wherein the trench defines a semiconductor body in the semiconductor substrate;
a high-k oxide filling the trench, wherein an interface state density (Dᵢₜ) at an interface between the high-k oxide and the semiconductor body is less than 2.0e11/cm²·eV; and
an interconnect stack over the second surface of the semiconductor substrate.

13. The CMOS image sensor of claim 12, wherein the interface state density (Dᵢₜ) is approximately 1.5e10/cm²·eV or less.

14. The CMOS image sensor of claim 12, wherein the high-k oxide comprises:
a first high-k liner along the surface of the trench; and
a high-k fill layer filling a remaining portion of the trench.

15. The CMOS image sensor of claim 14, further comprising:
a second high-k liner between the first high-k liner and the high-k fill layer.

16. The CMOS image sensor of claim 15, wherein the first high-k liner comprises Al₂O₃, wherein the second high-k liner comprises Ta₂O₅, and wherein the high-k fill layer comprises SiO₂.

17. The CMOS image sensor of claim 12, further comprising:
an anti-reflective coating over the first surface;
a filter over the anti-reflective coating; and
a lens over the filter.

18. The CMOS image sensor of claim 17, wherein the CMOS image sensor is a backside illuminated CMOS image sensor.

19. A method of forming a CMOS image sensor, comprising:
placing a substrate comprising a CMOS image sensor into a chamber, wherein the CMOS image sensor comprises:
a semiconductor substrate with a first surface and a second surface opposite from the first surface;
a trench into the first surface of the semiconductor substrate, wherein the trench defines a semiconductor body in the semiconductor substrate;
a high-k oxide filling the trench; and
an interconnect stack over the second surface of the semiconductor substrate;
pressurizing the chamber with a gas comprising H₂ and/or deuterium;
annealing the substrate in the pressurized chamber, wherein a pressure of the pressurized chamber is non-uniform during the annealing; and
depressurizing the chamber.

20. The method of claim 19, wherein a first interface state density (Dᵢₜ) of the CMOS image sensor before annealing is at least an order of magnitude higher than a second Dᵢₜ of the CMOS after annealing.
